(19) United States
(12) Patent Application Publication
(10) Pub. No.: US 2018/0277486 A1
(43) Pub. Date: Sep. 27, 2018

(54) SEMICONDUCTOR DEVICE AND METHOD OF MANUFACTURING THE SEMICONDUCTOR DEVICE

(71) Applicant: Renesas Electronics Corporation, Tokyo (JP)

(72) Inventor: Eiji HASEGAWA, Tokyo (JP)

(21) Appl. No.: 15/858,469

(22) Filed: Dec. 29, 2017

(30) Foreign Application Priority Data
Mar. 22, 2017 (JP) 2017-055426

(51) Int. Cl. H01L 23/532; H01L 23/522; H01L 21/02; H01L 21/768

(52) U.S. Cl. CPC H01L 23/53266; H01L 23/5226; H01L 21/76846; H01L 21/76814; H01L 21/02063

(57) ABSTRACT

Even if a via hole is displaced, erosion of a first layer made of titanium is suppressed when the via hole is cleaned. A semiconductor includes a wire layer, a side protective film, an interlayer insulating film, and via plugs. The wire layer includes a first layer made of titanium, a second layer that is arranged on the first layer and is made of titanium nitride, a third layer that is arranged on the second layer and contains aluminum, and a fourth layer that is arranged on the third layer and is made of titanium nitride. The side protective film is arranged on the side of the wire layer and has chemical resistance to hydroxylamine and conductivity. The interlayer insulating film covers the wire layer and the side protective film and has via holes. Via plugs are arranged in the via holes and are electrically coupled to the wire layer.

### CROSS-REFERENCE TO RELATED APPLICATIONS

The disclosure of Japanese Patent Application No. 2017-055426 filed on Mar. 22, 2017 including the specification, drawings and abstract is incorporated herein by reference in its entirety.

The present invention relates to a semiconductor device and a method of manufacturing the semiconductor device.

### BACKGROUND

Semiconductor devices described in Japanese Unexamined Patent Application Publication No. 2007-27254 and Japanese Unexamined Patent Application Publication No. 2013-4606 have been known in the related art.

The semiconductor device described in Japanese Unexamined Patent Application Publication No. 2007-27254 includes a wire layer, a protective film arranged on the sides and top surface of the wire layer, and an insulating layer covering the wire layer and the protective film. The wire layer includes a TiN (titanium nitride) film, an Al (aluminum)-Cu (copper) film arranged on the TiN film, a Ti (titanium) film arranged on the Al—Cu film, and a TiN film arranged on the Ti film. The protective film is a fluorinated silicate glass (FSG) film. In the semiconductor device described in Japanese Unexamined Patent Application Publication No. 2007-27254, the protective film prevents impurities in the insulating film from entering the wire layer, thereby suppressing malfunctions and so on of the semiconductor device.

The semiconductor device described in Japanese Unexamined Patent Application Publication No. 2013-4606 includes a first interlayer insulating film, a wire layer arranged on the first interlayer insulating film, a silicon nitride (SiN) film arranged on the sides and top surface of the wire layer, and a second interlayer insulating film covering the wire layer and the SiN film. The wire layer includes a lower TiN/Ti film, an AlCu film arranged on the lower TiN/Ti film, and an upper TiN/Ti film arranged on the AlCu film.

In the semiconductor device described in Japanese Unexamined Patent Application Publication No. 2013-4606, the first interlayer insulating film is etched after the formation of the wire layer and before the formation of the second interlayer insulating film. The SiN film at this point suppresses a repetition of etching on the side wall of the wire layer.

### SUMMARY

In the semiconductor device described in Japanese Unexamined Patent Application Publication No. 2007-27254, electrical coupling between wire layers requires the formation of via holes in the insulating layer by etching and the formation of via plugs in the via holes. If a mask is displaced when the insulating film is etched to form the via holes, the sides of the wire layer may be exposed from the via holes. In order to remove deposits remaining on the inner wall surfaces of the via holes after the etching for forming the via holes, the inner wall surfaces of the via holes may be cleaned with a chemical solution containing hydroxylamine.

In the semiconductor device described in Japanese Unexamined Patent Application Publication No. 2007-27254, the Ti film including the wire layer has a high etching rate relative to the chemical solution containing hydroxylamine. Thus, if the mask is displaced during etching for forming the via holes in the semiconductor device described in Japanese Unexamined Patent Application Publication No. 2007-27254, the chemical solution containing hydroxylamine may erode the Ti film including the wire layer.

In the semiconductor device described in Japanese Unexamined Patent Application Publication No. 2013-4606, the etching rate of the SiN film is lower than that of the second interlayer insulating film. Thus, when the second interlayer insulating film is etched to form the via holes, the sides of the wire layer are not exposed. However, the SiN film is an insulating film and thus the via plugs formed with the remaining SiN film cannot electrically couple wires. Hence, the SiN film also needs to be removed by etching in the end. The removal of the SiN film by etching may cause deposits again, resulting in the same problem in the semiconductor device described in Japanese Unexamined Patent Application Publication No. 2013-4606 as in the semiconductor device described in Japanese Unexamined Patent Application Publication No. 2007-27254.

In order to suppress electromigration of the AlCu film, the AlCu film needs to have uniform crystalline orientation. The crystalline orientation of the AlCu film is affected by the crystalline orientation of the TiN film arranged under the AlCu film. If the TiN film is formed immediately above the first interlayer insulating film, it is difficult to ensure the uniformity of the crystalline orientation of the TiN film. Thus, it is actually difficult to eliminate the need for the Ti film in a semiconductor device according to the Japanese Unexamined Patent Application Publication No. 2013-4606.

Other problems and new characteristics will be clarified by a description of the present specification and the accompanying drawings.

A semiconductor device according to an embodiment includes a wire layer including a first layer made of titanium, a second layer that is arranged on the first layer and is made of titanium nitride, a third layer that is arranged on the second layer and contains aluminum, and a fourth layer that is arranged on the third layer and is made of titanium nitride; a side protective film that is arranged on the side of the wire layer and has chemical resistance to hydroxylamine and conductivity; an interlayer insulating film that covers the wire layer and the side protective film and has via holes; and via plugs that are arranged in the via holes and are electrically coupled to the wire layer.

In the semiconductor device according to the embodiment, even if the via hole is displaced from the wire layer, erosion of the first layer made of titanium can be suppressed when the inner wall surface of the via hole is cleaned.

### BRIEF DESCRIPTION OF THE DRAWINGS

FIG. 1 is a cross-sectional view showing a semiconductor device according to a first embodiment;

FIG. 2 is an enlarged view of a region II in FIG. 1;

FIG. 3 is a process drawing showing a method of manufacturing the semiconductor device according to the first embodiment;

FIG. 4 is a cross-sectional view showing the semiconductor device according to the first embodiment after the completion of a front-end step;

FIG. 5 is a cross-sectional view showing the semiconductor device according to the first embodiment after the completion of a pre-metal insulating film forming step;

FIG. 6 is a cross-sectional view showing the semiconductor device according to the first embodiment after the completion of a contact hole forming step;

FIG. 7 is a cross-sectional view showing the semiconductor device according to the first embodiment after the completion of a contact plug forming step;

FIG. 8 is a cross-sectional view showing the semiconductor device according to the first embodiment after the completion of a first wire-layer forming step;

FIG. 9 is a cross-sectional view showing the semiconductor device according to the first embodiment after the completion of a side protective-film forming step;

FIG. 10 is a cross-sectional view showing the semiconductor device according to the first embodiment after the completion of an interlayer insulating-film forming step;

FIG. 11 is a cross-sectional view showing the semiconductor device according to the first embodiment after the completion of a via hole forming step;

FIG. 12 is a cross-sectional view showing the semiconductor device according to the first embodiment after the completion of a deposit removing step;

FIG. 13 is a cross-sectional view showing the semiconductor device according to the first embodiment after the completion of a via plug forming step;

FIG. 14 is a cross-sectional view showing a semiconductor device according to a comparative example in which a via hole is displaced from a first wire layer;

FIG. 15 is a cross-sectional view showing the semiconductor device according to the first embodiment in which a via hole is displaced from a first wire layer;

FIG. 16 is a cross-sectional view showing a semiconductor device according to a second embodiment;

FIG. 17 is an enlarged view of a region XVII in FIG. 16;

FIG. 18 is a cross-sectional view showing the semiconductor device according to the second embodiment in which a via hole is displaced from a first wire layer;

FIG. 19 is a cross-sectional view showing a semiconductor device according to a third embodiment;

FIG. 20 is an enlarged view of a region XX in FIG. 19;

FIG. 21 is a cross-sectional view showing a semiconductor device according to a fourth embodiment;

FIG. 22 is an enlarged view of a region XXII in FIG. 21; and

FIG. 23 is a cross-sectional view showing the semiconductor device according to the fourth embodiment after the completion of a first wire-layer forming step.

### DETAILED DESCRIPTION

Embodiments will be described below with reference to the accompanying drawings. In the drawings, the same or equivalent parts are indicated by the same reference numerals and the explanation thereof is not repeated.

### First Embodiment

The configuration of a semiconductor device according to a first embodiment will be described below.

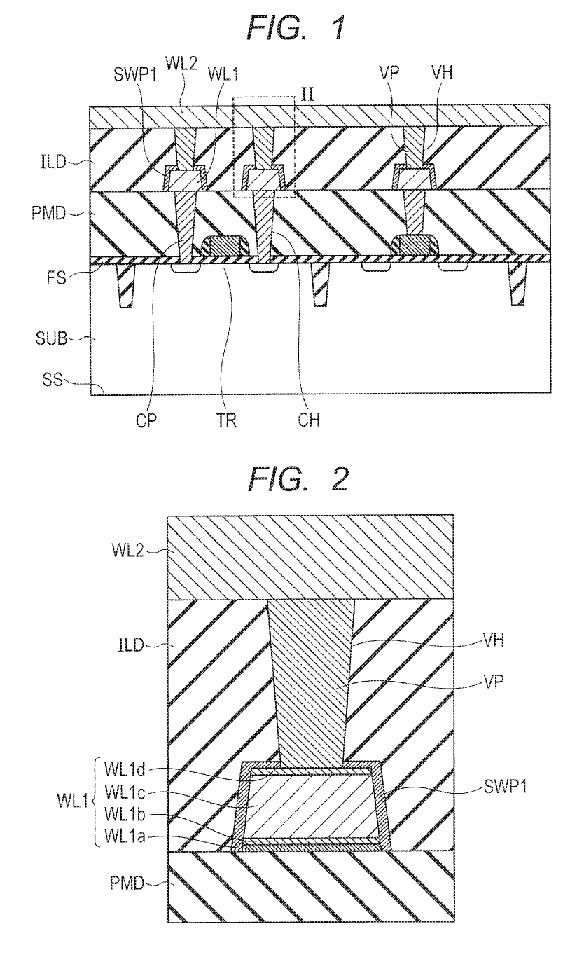

First, the overall configuration of the semiconductor device according to the first embodiment will be described below. As shown in FIG. 1, the semiconductor device according to the first embodiment includes a semiconductor substrate SUB, a pre-metal insulating film PMD, a first wire layer WL1, a side protective film SWP1, contact plugs CP, an interlayer insulating film ILD, a second wire layer WL2, and via plugs VP.

The semiconductor substrate SUB has a first surface FS and a second surface SS. The second surface SS is opposite to the first surface FS. On the first surface of the semiconductor substrate SUB, semiconductor elements such as a transistor TR are formed. The semiconductor substrate SUB is made of, for example, single crystal silicon (Si).

The pre-metal insulating film PMD is arranged on the first surface FS of the semiconductor substrate SUB. The pre-metal insulating film PMD is made of, for example, silicon dioxide (SiO₂). The pre-metal insulating film PMD has contact holes CH. The contact holes CH are arranged on the source region, the drain region, and the gate electrode of the transistor TR. The contact holes CH penetrate the pre-metal insulating film PMD so as to intersect the first surface FS. In other words, the contact holes CH are provided so as to expose the source regions, the drain regions, and the gate electrodes of the transistors TR from the pre-metal insulating film PMD.

The first wire layer WL1 is arranged on the pre-metal insulating film PMD. The configuration of the first wire layer WL1 will be specifically discussed later. The side protective film SWP1 is arranged on the sides of the first wire layer WL1. The side protective film SWP1 has chemical resistance to hydroxylamine and is made of a conductive material. The chemical resistance of the side protective film SWP1 to hydroxylamine means that the etching rate of the side protective film SWP1 relative to a chemical solution containing hydroxylamine is lower than the etching rate of TiO₂ contained in a deposit DP relative to a chemical solution containing hydroxylamine. The configuration of the side protective film SWP1 will be specifically described later.

The contact plugs CP are arranged in the contact holes CH. The contact plugs CP are electrically coupled to the source region, the drain region, and the gate electrode of the transistor TR. The contact plugs CP are electrically coupled to the first wire layer WL1. The contact plugs CP are made of, for example, tungsten (W).

The interlayer insulating film ILD is arranged on the pre-metal insulating film PMD. The interlayer insulating film ILD is arranged over the first wire layer and the side protective film SWP1. The interlayer insulating film ILD is made of, for example, SiO₂.

The interlayer insulating film ILD has via holes VH. The via holes VH penetrate the interlayer insulating film ILD in a direction intersecting the first surface FS. The via holes VH are arranged on the first wire layer WL1. In other words, the via holes VH are provided so as to expose the first wire layer WL1 from the interlayer insulating film ILD.

The second wire layer WL2 is arranged on the interlayer insulating film ILD. The configuration of the second wire layer WL2 is identical to that of the first wire layer WL1. The side protective film SWP1 may be arranged on the side of the second wire layer WL2.

The via plugs VP are arranged in the via holes VH. The via plugs VP are electrically coupled to the first wire layer WL1. Moreover, the via plugs VP are electrically coupled to the second wire layer WL2. The via plugs VP are made of, for example, W.

FIG. 1 illustrates the two wire layers. Three or more wire layers may be provided.

The configuration of the first wire layer WL1 and the side protective film SWP1 will be specifically described below. As shown in FIG. 2, the first wire layer WL1 includes a first layer WL1a, a second layer WL1b, a third layer WL1c, and a fourth layer WL1d.

The first layer WL1a is made of Ti. The first layer WL1a is arranged on the pre-metal insulating film PMD. The second layer WL1b is made of TiN. The second layer WL1b is arranged on the first layer WL1a.

The third layer WL1c contains Al. For example, the third layer WL1c is included of an AlCu alloy. The third layer WL1c is arranged on the second layer WL1b. The fourth layer WL1d is made of TiN. The fourth layer WL1d is arranged on the third layer WL1c.

The side protective film SWP1 is made of a nitride of a material of the first wire layer WL1. Specifically, the side protective film SWP1 arranged on the sides of the first layer WL1a, the second layer WL1b, and the fourth layer WL1d is made of TiN, whereas the side protective film SWP1 arranged on the sides of the third layer WL1c is made of AlCuN.

A method of manufacturing the semiconductor device according to the first embodiment will be described below.

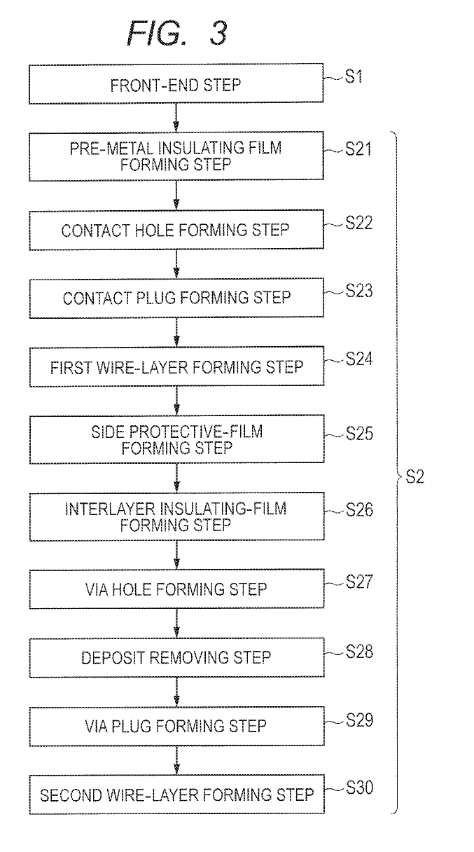

As shown in FIG. 3, the semiconductor device according to the first embodiment has a front-end step S1 and a back-end step S2.

The back-end step S2 includes a pre-metal insulating film forming step S21, a contact hole forming step S22, a contact plug forming step S23, a first wire-layer forming step S24, a side protective-film forming step S25, an interlayer insulating-film forming step S26, a via hole forming step S27, a deposit removing step S28, a via plug forming step S29, and a second wire-layer forming step S30.

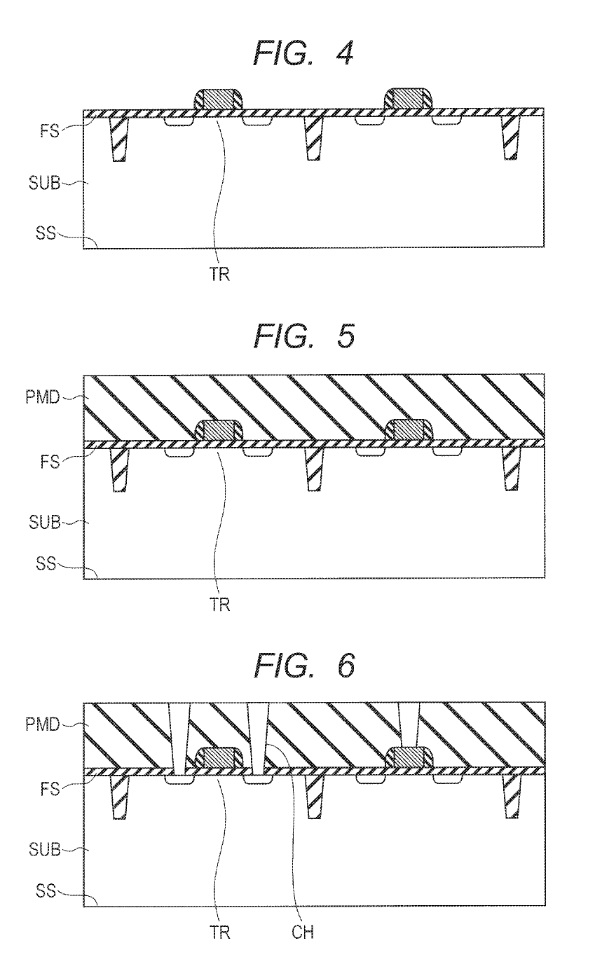

As shown in FIG. 4, in the front-end step Si, the transistor TR is formed on the first surface FS of the semiconductor substrate SUB. The transistor TR is formed by a known method. For example, the source region, the well region, and the drain region of the transistor TR are formed by ion implantation. The gate insulating film of the transistor TR is formed by, for example, thermal oxidation on the first surface FS of the semiconductor substrate SUB. The gate electrode of the transistor TR is formed by, for example, chemical vapor deposition (CVD) on polycrystalline silicon doped with an impurity and patterning according to photolithography of deposited polycrystalline silicon.

As shown in FIG. 5, in the pre-metal insulating film forming step S21, the pre-metal insulating film PMD is formed on the first surface FS of the semiconductor substrate SUB. In the formation of the pre-metal insulating film PMD, the material of the pre-metal insulating film PMD is first deposited. The material of the pre-metal insulating film PMD is deposited by, for example, CVD.

In the formation of the pre-metal insulating film PMD, secondly, the deposited material of the pre-metal insulating film PMD is flattened. The deposited material of the pre-metal insulating film PMD is flattened by, for example, chemical mechanical polishing (CMP).

As shown in FIG. 6, in the contact hole forming step S22, the contact holes CH are formed in the pre-metal insulating film PMD. The contact holes CH are formed by anisotropic etching, e.g., reactive ion etching (RIE).

As shown in FIG. 7, in the contact plug forming step S23, the contact plugs CP are formed in the contact holes CH. The contact plugs CP are formed by filling the contact holes CH with the material of the contact plugs CP by, for example, CVD and then removing the protrusions of the material of the contact plugs CP from the contact holes CH by CMP.

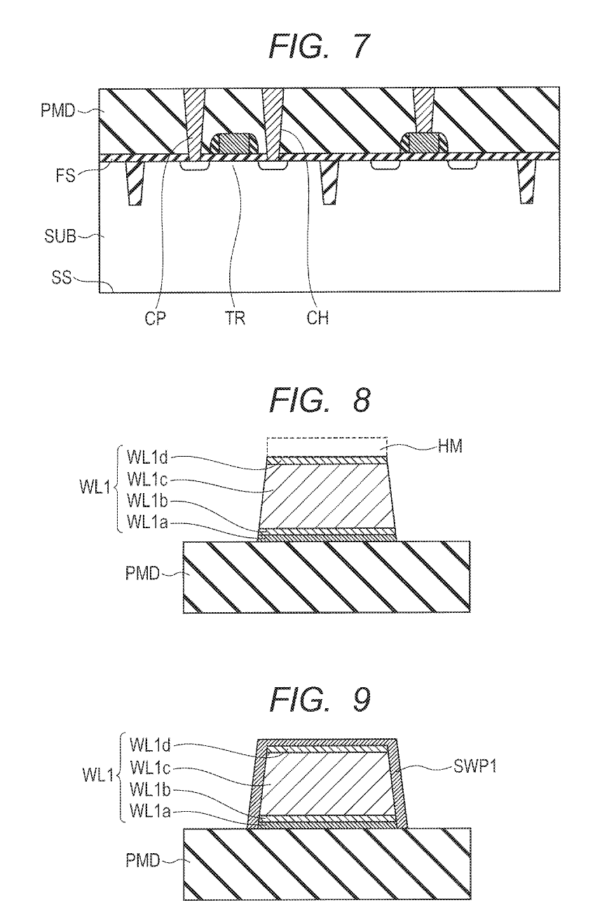

As shown in FIG. 8, in the first wire-layer forming step S24, the first wire layer WL1 is formed on the pre-metal insulating film PMD. In the formation of the first wire layer WL1, first, the materials of the first layer WL1a, the second layer WL1b, the third layer WL1c, and the fourth layer WL1d are sequentially deposited on the pre-metal insulating film PMD by sputtering and so on.

In the formation of the first wire layer WL1, secondly, a hard mask HM is formed on the fourth layer WL1d. The hard mask HM is formed by depositing the material (e.g., SiO₂) of the hard mask HM on the fourth layer WL1d and then patterning the deposited material of the hard mask HM by photolithograpy.

In the formation of the first wire layer WL1, thirdly, the deposited materials of the first layer WL1a, the second layer WL1b, the third layer WL1c, and the fourth layer WL1d are subjected to anisotropic etching, e.g., RIE by using the hard mask HM.

As shown in FIG. 9, in the side protective-film forming step S25, the side protective film SWP1 is formed on the sides and the top surface of the first wire layer WL1. The side protective film SWP1 is formed by nitriding the sides of the first wire layer WL1. The nitriding on the sides of the first wire layer WL1 is, for example, plasma nitriding.

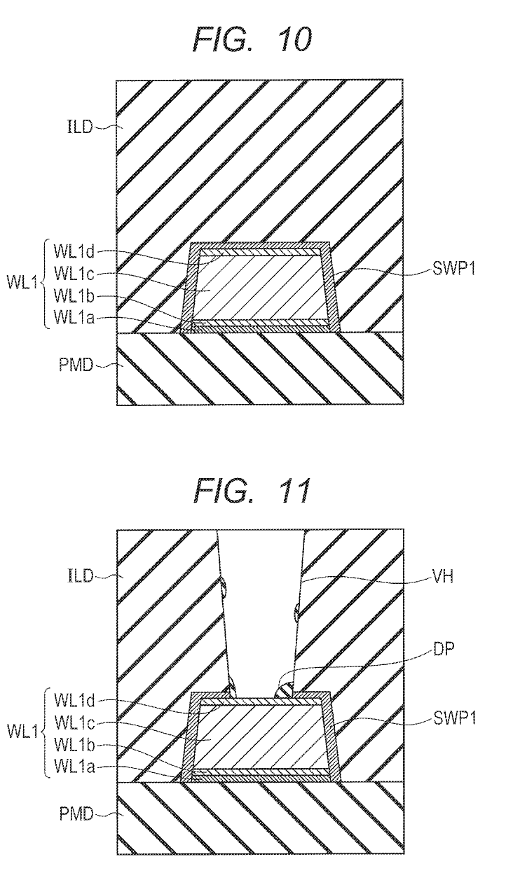

As shown in FIG. 10, in the interlayer insulating-film forming step S26, the interlayer insulating film ILD is formed over the first wire layer WL1 and the side protective film SWP1. The interlayer insulating film ILD is formed by depositing the material of the interlayer insulating film ILD over the first wire layer WL1 and the side protective film SWP1 by CVD and so on and flattening the top surface of the deposited material of the interlayer insulating film ILD by CMP and so on.

As shown in FIG. 11, in the via hole forming step S27, the via hole VH is formed in the interlayer insulating film ILD. The via hole VH is formed by, for example, anisotropic etching such as RIE. In this case, the deposit DP may be left on the inner wall of the formed via hole VH. The deposit DP contains TiO₂.

As shown in FIG. 12, in the deposit removing step S28, the deposit DP remaining on the inner wall surface of the via hole VH is removed. The deposit DP is removed by cleaning the inner wall surface of the via hole VH with a chemical solution containing hydroxylamine.

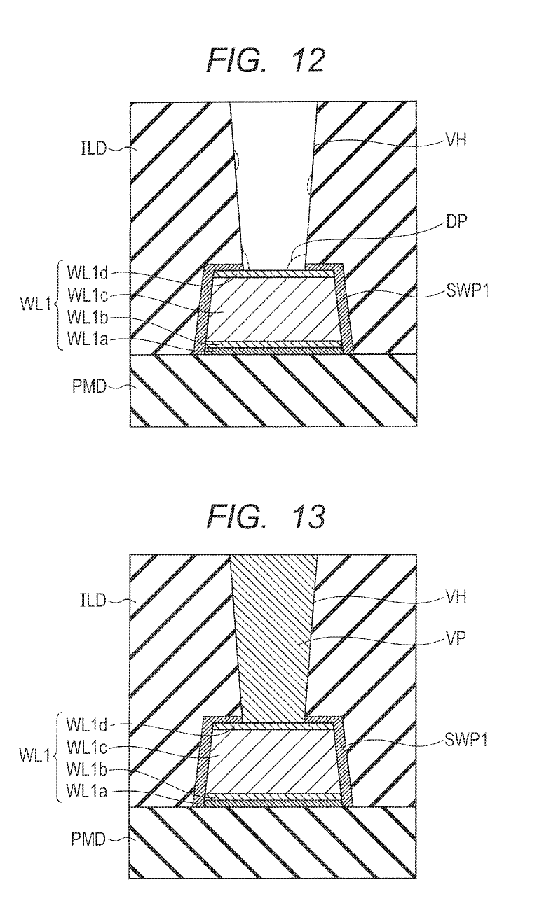

As shown in FIG. 13, in the via plug forming step S29, the via plug VP is formed in the via hole VH. The via plug VP is formed by filling the via hole VH with the material of the via plug VP by, for example, CVD and then removing the protrusion of the material of the via plug VP from the via hole VH by CMP.

In the second wire layer forming step S30, the second wire layer WL2 is formed on the interlayer insulating film ILD. The second wire layer WL2 is formed by the same method as the first wire layer WL1. This forms the structure of the semiconductor device according to the first embodiment shown in FIGS. 1 and 2. The steps from the first wire layer forming step S24 to the second wire layer forming step S30 are repeated so as to manufacture a semiconductor device having a larger number of wire layers.

The effect of the semiconductor device according to the first embodiment will be described below in comparison with a comparative example.

A semiconductor device according to the comparative example is different from the semiconductor device according to the first embodiment in that the side protective film SWP1 is not provided.

In the semiconductor device according to the comparative example, as shown in FIG. 14, the via hole VH may be displaced from the first wire layer WL1. Hence, in the semiconductor device according to the comparative example, the first wire layer WL1 may be exposed from the inner wall surface of the via hole VH.

Titanium making up the first layer WL1a has a higher etching rate than TiO₂ contained in the deposit DP relative to a chemical solution containing hydroxylamine (TiO₂ contained in the deposit DP has an etching rate of 0.12 nm/min relative to the chemical solution containing hydroxylamine, whereas titanium has an etching rate of 4.3 nm/min relative to the chemical solution containing hydroxylamine).

Thus, in the semiconductor device according to the comparative example, when the inner wall surfaces of the via holes VH are cleaned with the chemical solution containing hydroxylamine in order to remove the deposit DP, the first layer WL1a is eroded by the chemical solution containing hydroxylamine. This reduces the reliability of the first wire layer WL1.

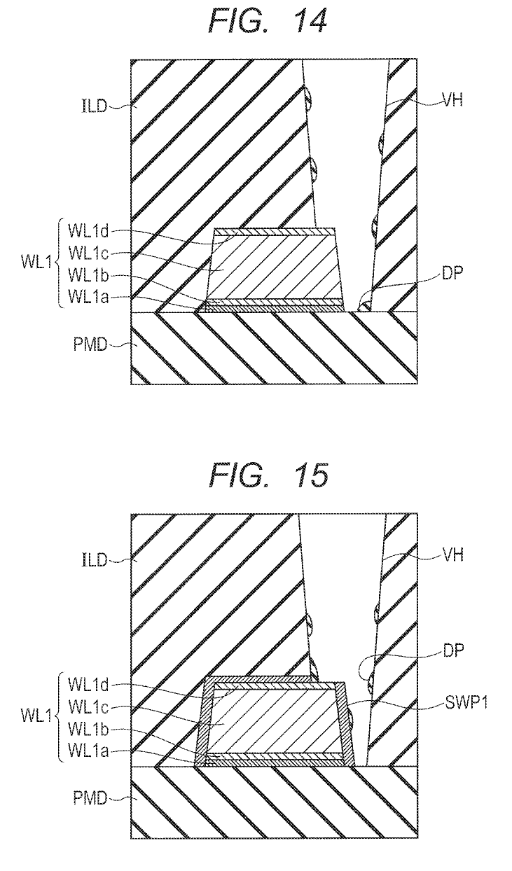

As shown in FIG. 15, also in the semiconductor device according to the first embodiment, the via hole VH may be displaced from the first wire layer WL1. In the semiconductor device according to the first embodiment, as described above, the side protective film SWP1 is arranged on the sides of the first wire layer WL1. Hence, even if the via hole VH is displaced from the first wire layer WL1, the side protective film SWP1 is exposed from the inner wall surface of the via hole VH instead of the side of the first wire layer WL1.

The side protective film SWP1 is resistant to a chemical solution containing hydroxylamine (For example, TiN has an etching rate of less than 0.01 nm/min relative to a chemical solution containing hydroxylamine). Thus, when the inner wall surface of the via hole VH is cleaned with a chemical solution containing hydroxylamine in order to remove the deposit DP, the first layer WL1a is hardly eroded by the chemical solution containing hydroxylamine.

The side protective film SWP1 has conductivity, eliminating the need for removing the side protective film SWP1 after the inner wall surface of the via hole VH is cleaned with a chemical solution containing hydroxylamine in order to remove the deposit DP. Since the side protective film SWP1 does not need to be removed, the deposit DP is not generated again during the removal of the side protective film SWP1. Hence, in the semiconductor device according to the first embodiment, erosion of the first layer WL1a made of titanium can be suppressed when the inner wall surface of the via hole VH is cleaned.

In the semiconductor device according to the first embodiment, if the side protective film SWP1 is made of a nitride of a material of the first wire layer WL1, the side protective film SWP1 can be reduced in thickness by plasma nitriding and so on. The larger the thickness of the side protective film SWP1, the smaller the intervals between wires. The smaller the intervals between the wires, the more difficult the embedding of the material of the interlayer insulating film ILD between the wires. Thus, in this case, the embedding of the interlayer insulating film ILD can be improved.

### Second Embodiment

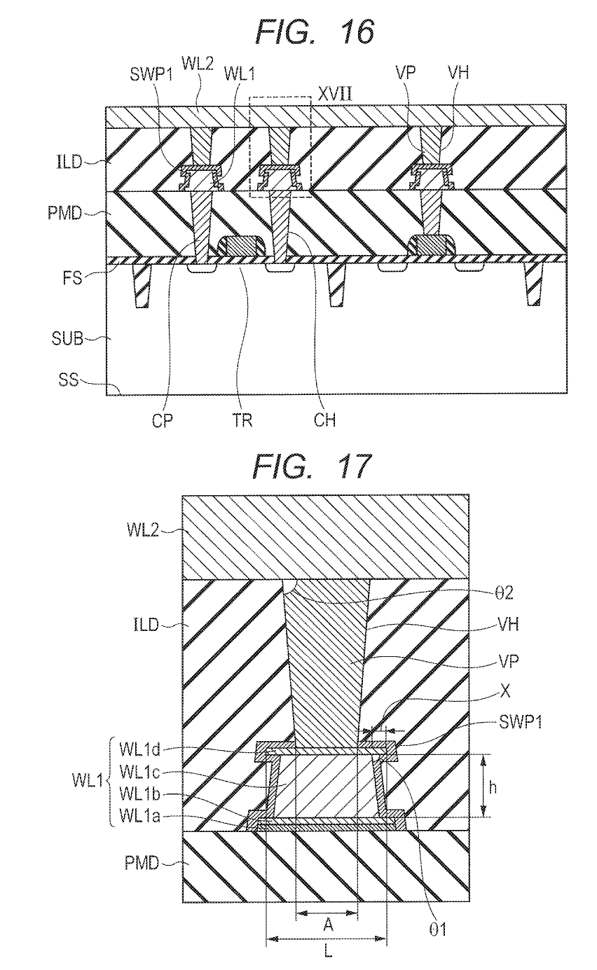

As shown in FIG. 16, a semiconductor device according to a second embodiment includes a semiconductor substrate SUB, a pre-metal insulating film PMD, contact plugs CP, a first wire layer WL1, a side protective film SWP1, an interlayer insulating film ILD, and a second wire layer WL2.

As shown in FIG. 17, in the semiconductor device according to the second embodiment, the first wire layer WL1 includes a first layer WL1a, a second layer WL1b, a third layer WL1c, and a fourth layer WL1d. In view of these points, the semiconductor device according to the second embodiment shares a common configuration with the semiconductor device according to the first embodiment. However, the semiconductor device according to the second embodiment is different from the semiconductor device according to the first embodiment in the detail of the configuration of the first wire layer WL1.

In the semiconductor device according to the second embodiment, the fourth layer WL1d is laterally protruded from the side of the third layer WL1c positioned near the fourth layer WL1d. The fourth layer WL1d has a width L. The fourth layer WL1d is laterally protruded by a distance X from the side of the third layer WL1c positioned near the fourth layer WL1d.

The third layer WL1c is tapered. The third layer WL1c increases in width from the fourth layer WL1d toward the second layer WL1b. An angle θ1 is formed between the side of the third layer WL1c and the fourth layer WL1d. The third layer WL1c has a thickness h that is a distance between the surfaces of the third layer WL1c near the fourth layer WL1d and the second layer WL1b.

A via hole VH is tapered. The via hole VH decreases in opening width from the top surface of the interlayer insulating film ILD toward the undersurface of the interlayer insulating film ILD. The opening width of the via hole VH is a distance between the opposed inner wall surfaces. The via hole VH has an opening width A at the same height as the top surface of the first wire layer WL1. Moreover, a distance between the center of the via hole VH and the center of the first wire layer WL1 is denoted as a displacement Y. An angle θ2 is formed between the inner wall surface of the via hole VH and the top surface of the interlayer insulating film ILD.

The distance X, the angle θ1, the angle θ2, and the thickness h preferably satisfy the relationship of X>h×(tan θ2−tan θ1/(tan θ1×tan θ2). The distance X, the angle θ1, the angle θ2, the width L, the opening width A, and the displacement Y preferably satisfy the relationship of X>(A/2+Y−L/2)×(tan θ2−tan θ1)/2×tan θ1.

A method of manufacturing the semiconductor device according to the second embodiment includes a front-end step S1 and a back-end step S2. The back-end step S2 includes a pre-metal insulating film forming step S21, a contact hole forming step S22, a contact plug forming step S23, a first wire-layer forming step S24, a side protective-film forming step S25, an interlayer insulating-film forming step S26, a via hole forming step S27, a deposit removing step S28, a via plug forming step S29, and a second wire-layer forming step S30. In view of these points, the semiconductor device according to the second embodiment shares a common manufacturing method with the semiconductor device according to the first embodiment.

However, the method of manufacturing the semiconductor device according to the second embodiment is different from the method of manufacturing the semiconductor device according to the first embodiment in the details of the first wire-layer forming step S24 and the via hole forming step S27.

In the first wire-layer forming step S24, the fourth layer WL1d is formed so as to laterally protrude from the third layer WL1c. The fourth layer WL1d laterally protruding from the third layer WL1c can be formed by controlling a gas flow rate during anisotropic etching such as RIE. For example, by controlling the flow rate of a component (e.g., methane) that is a cause of a by-product contained in reactant gas during anisotropic etching such as RIE, the amount of the by-product deposited on the side of the third layer WL1c during etching is changed. This relatively encourages etching on the third layer WL1c, laterally protruding the fourth layer WL1d from the third layer WL1c.

In the first wire-layer forming step S24, the third layer WL1c is tapered so as to increase in width from the fourth layer WL1d toward the second layer WL1b. The third layer WL1c tapered so as to increase in width from the fourth layer WL1d toward the second layer WL1b can be formed by controlling a gas flow rate during anisotropic etching such as RIE. For example, by controlling the flow rate of a component that is a cause of a by-product contained in reactant gas during anisotropic etching such as RIE, the amount of the by-product deposited on the side of the third layer WL1c during etching is changed. Hence, the width of a groove formed by etching decreases with the progress of etching, increasing the width of the third layer WL1c from the fourth layer WL1d toward the second layer WL1b.

In the via hole forming step S27, the via hole VH is formed so as to decrease in opening width from the top surface of the interlayer insulating film ILD toward the undersurface of the interlayer insulating film ILD. The via hole VH with an opening width decreasing from the top surface toward the undersurface of the interlayer insulating film ILD is formed by controlling a gas flow rate during anisotropic etching such as RIE. For example, by controlling the flow rate of a component that is a cause of a by-product contained in reactant gas during anisotropic etching such as RIE, the amount of the by-product deposited on the side of the via hole VH during etching is changed. Hence, the width of the via hole VH is reduced by etching with the progress of etching.

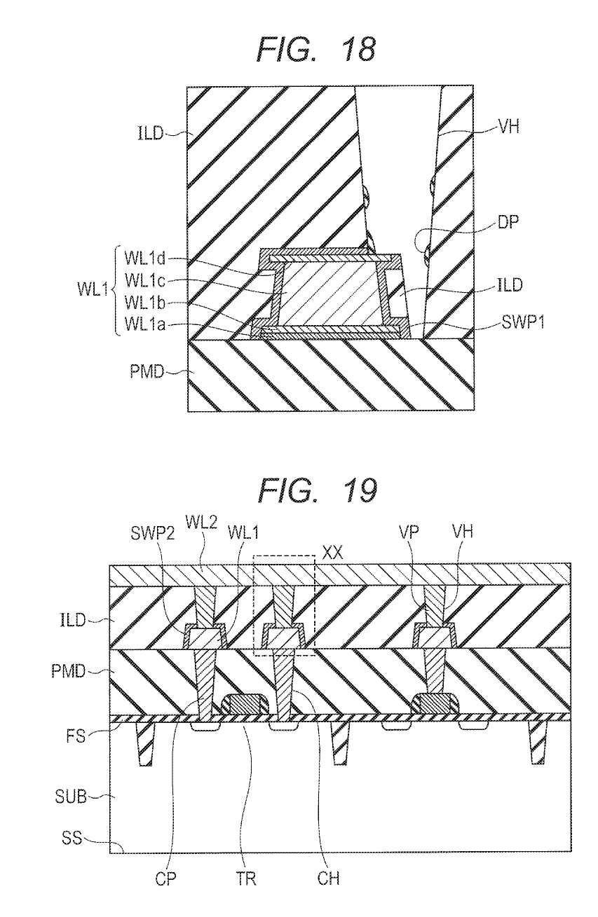

The interlayer insulating film ILD is hardly etched under the fourth layer WL1d in the via hole forming step S27. Thus, in this case, even if the via hole VH is displaced from the first wire layer WL1 as shown in FIG. 18, the interlayer insulating film ILD is likely to remain between the side protective film SWP1 arranged on the side of the third layer WL1c and the inner wall surface of the via hole VH.

As described above, the side protective film SWP1 formed on the side of the first wire layer WL1 is made of a nitride of a material of the first wire layer WL1. For this reason, the side protective film SWP1 arranged on the side of the third layer WL1c is made of AlCuN. The etching rate of AlCuN relative to a chemical solution containing hydroxylamine is relatively high.

In contrast, the material (e.g., SiO₂) of the interlayer insulating film ILD has an extremely low etching rate relative to a chemical solution containing hydroxylamine. Thus, in the semiconductor device according to the second embodiment, even if the via hole VH is displaced from the first wire layer WL1, erosion by a chemical solution containing hydroxylamine can be suppressed on the side protective film SWP1 arranged on the side of the third layer WL1c.

The side of the third layer WL1c forms the angle θ1 with respect to the fourth layer WL1d. Thus, the side of the third layer WL1c near the second layer WL1b is laterally displaced from the side of the third layer WL1c near the fourth layer WL1d by about h/tan θ1.

The inner wall surface of the via hole VH forms the angle θ2 with respect to the top surface of the interlayer insulating film ILD. The fourth layer WL1d is protruded by a distance X from the side of the third layer WL1c near the fourth layer WL1d. Thus, at the same height as one surface of the third layer WL1c near the second layer WL1b, the inner wall surface of the via hole VH is laterally displaced by about X+h/tan θ2 from the side of the third layer WL1c near the second layer WL1b.

Thus, if the relationship of X+h/tan θ2>h/tan θ1 is satisfied, that is, the relationship of X>h×(tan θ2−tan θ1)/(tan θ1×tan θ2) is satisfied, the side of the third layer WL1c is completely covered with the interlayer insulating film ILD. Thus, in the semiconductor device according to the second embodiment, if the relationship of X>h×(tan θ2−tan θ1)/(tan θ1×tan θ2) is satisfied, erosion by a chemical solution containing hydroxylamine can be further suppressed on the side protective film SWP1 arranged on the side of the third layer WL1c.

If the via hole VH is displaced from the first wire layer WL1 by Y, a distance between the inner wall surface of the via hole VH and the fourth layer WL1d is about A/2+Y−L/2. The bottom of the via hole VH is laterally displaced from the fourth layer WL1d by about (A/2+Y−L/2)/2. The bottom of the via hole VH is arranged lower than one surface of the third layer WL1c near the fourth layer WL1d by about tan θ2×(A/2+Y−L/2)/2.

The side of the third layer WL1c laterally displaced from the fourth layer WL1d by (A/2+Y−L/2) is arranged lower than the height of one surface of the third layer WL1c near the fourth layer WL1d by about tan θ1×{X+(A/2+Y−L/2)/2}.

Thus, if the relationship of tan θ1×{X+(A/2+Y−L/2)/2}>tan θ2×(A/2+Y−L/2)/2 is satisfied, that is, the relationship of X>(A/2+Y−L/2)×(tan θ2−tan θ1)/2×tan θ1 is satisfied, the side of the third layer WL1c is completely covered with the interlayer insulating film ILD. Thus, in this case, erosion by a chemical solution containing hydroxylamine can be further suppressed on the side protective film SWP1 arranged on the side of the third layer WL1c.

### Third Embodiment

As shown in FIG. 19, a semiconductor device according to a third embodiment includes a semiconductor substrate SUB, a pre-metal insulating film PMD, contact plugs CP, a first wire layer WL1, an interlayer insulating film ILD, and a second wire layer WL2.

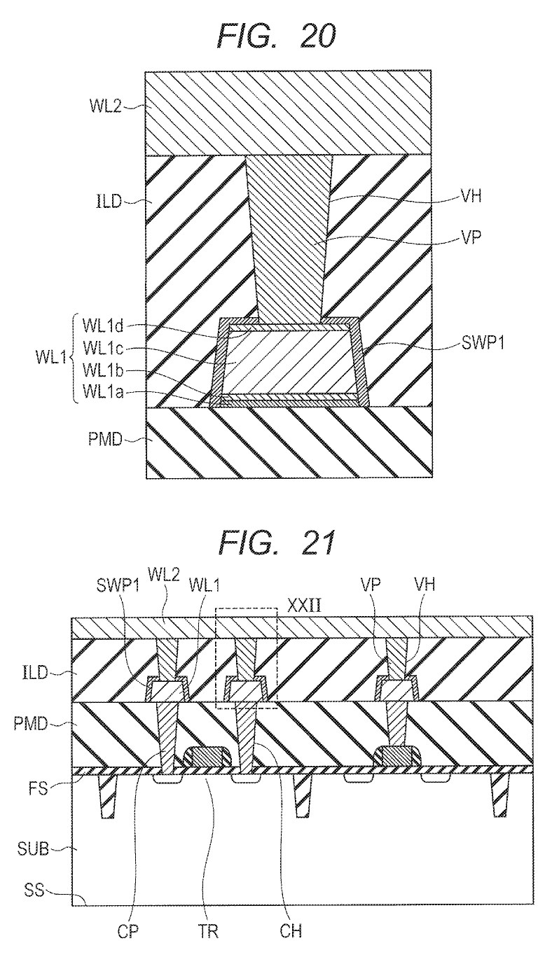

As shown in FIG. 20, in the semiconductor device according to the third embodiment, the first wire layer WL1 includes a first layer WL1a, a second layer WL1b, a third layer WL1c, and a fourth layer WL1d. In view of these points, the semiconductor device according to the third embodiment shares a common configuration with the semiconductor device according to the first embodiment. However, the semiconductor device according to the third embodiment is different from the semiconductor device according to the first embodiment in that the side protective film SWP1 is replaced with a side protective film SWP2.

The side protective film SWP2 is arranged on the side of the first wire layer WL1. The side protective film SWP2 has chemical resistance to a chemical solution containing hydroxylamine. The side protective film SWP2 has conductivity. The side protective film SWP2 is a sputtering film or a CVD film. In this case, a sputtering film is a film formed by sputtering and a CVD film is a film deposited by CVD. The side protective film SWP2 is preferably made of TiN.

A method of manufacturing the semiconductor device according to the third embodiment includes a front-end step S1 and a back-end step S2. The back-end step S2 includes a pre-metal insulating film forming step S21, a contact hole forming step S22, a contact plug forming step S23, a first wire-layer forming step S24, a side protective-film forming step S25, an interlayer insulating-film forming step S26, a via hole forming step S27, a deposit removing step S28, a via plug forming step S29, and a second wire-layer forming step S30. In view of these points, the semiconductor device according to the third embodiment shares a common manufacturing method with the semiconductor device according to the first embodiment.

However, the method of manufacturing the semiconductor device according to the third embodiment is different from the method of manufacturing the semiconductor device according to the first embodiment in that the side protective-film forming step S25 is performed by CVD or sputtering.

In the semiconductor device according to the third embodiment, even if a via hole VH is displaced from the first wire layer WL1, erosion of the first layer WL1a can be suppressed as in the semiconductor device according to the first embodiment, the first layer WL1a being eroded by a chemical solution containing hydroxylamine used when a deposit DP is removed.

If the side protective film SWP2 is a CVD film in the semiconductor device according to the third embodiment, the side protective film SWP2 can be formed into a conformal shape. Thus, in this case, erosion of the first layer WL1a can be further suppressed, the first layer WL1a being eroded by a chemical solution containing hydroxylamine used when the deposit DP is removed.

### Fourth Embodiment

As shown in FIG. 21, a semiconductor device according to a fourth embodiment includes a semiconductor substrate SUB, a pre-metal insulating film PMD, contact plugs CP, a first wire layer WL1, a side protective film SWP1, an interlayer insulating film ILD, and a second wire layer WL2.

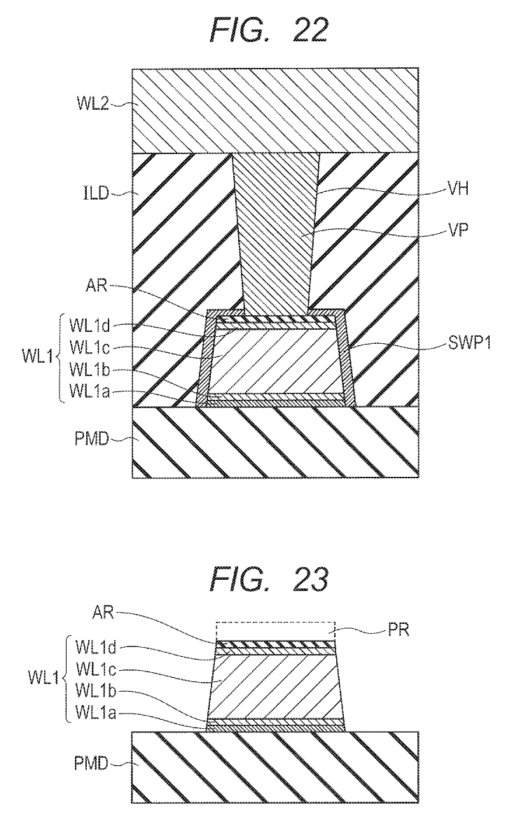

As shown in FIG. 22, in the semiconductor device according to the fourth embodiment, the first wire layer WL1 includes a first layer WL1a, a second layer WL1b, a third layer WL1c, and a fourth layer WL1d. In view of these points, the semiconductor device according to the fourth embodiment shares a common configuration with the semiconductor device according to the first embodiment.

However, the semiconductor device according to the fourth embodiment is different from the semiconductor device according to the first embodiment in that an antireflection film AR is further provided.

The antireflection film AR is arranged on the fourth layer WL1d. The antireflection film AR is a film for suppressing reflection during photolithography on the first wire layer WL1. The antireflection film AR is made of, for example, silicon oxynitride (SiON).

A method of manufacturing the semiconductor device according to the fourth embodiment includes a front-end step S1 and a back-end step S2. The back-end step S2 includes a pre-metal insulating film forming step S21, a contact hole forming step S22, a contact plug forming step S23, a first wire-layer forming step S24, a side protective-film forming step S25, an interlayer insulating-film forming step S26, a via hole forming step S27, a deposit removing step S28, a via plug forming step S29, and a second wire-layer forming step S30. In view of these points, the semiconductor device according to the fourth embodiment shares a common manufacturing method with the semiconductor device according to the first embodiment.

However, the method of manufacturing the semiconductor device according to the fourth embodiment is different from the method of manufacturing the semiconductor device according to the first embodiment in the detail of the first wire-layer forming step S24.

As shown in FIG. 23, in the first wire-layer forming step S24, the first wire layer WL1 is formed on the pre-metal insulating film PMD. In the first wire-layer forming step S24, the antireflection film AR is formed on the first wire layer WL1.

In the first wire-layer forming step S24, first, the materials of the first layer WL1a, the second layer WL1b, the third layer WL1c, and the fourth layer WL1d are sequentially deposited on the pre-metal insulating film PMD by sputtering and so on. In the first wire-layer forming step S24, secondly, the material of the antireflection film AR is deposited on the fourth layer WL1d. The antireflection film AR is deposited by, for example, CVD.

In the first wire-layer forming step S24, thirdly, the materials of the antireflection film AR, the first layer WL1a, the second layer WL1b, the third layer WL1c, and the fourth layer WL1d are patterned. Thirdly, the materials of the antireflection film AR, the first layer WL1a, the second layer WL1b, the third layer WL1c, and the fourth layer WL1d are patterned by photolithography using a photoresist PR.

If the first wire layer WL1 is formed by photolithography using the photoresist PR, the antireflection film AR is preferably used to improve the accuracy of form of the photoresist PR. Etching on the material of the antireflection film AR encourages the generation of a deposit DP. In the semiconductor device according to the fourth embodiment, even if the first wire layer WL1 is formed by photolithography using the photoresist PR, erosion of the first layer WL1a can be suppressed, the first layer WL1a being eroded by a chemical solution containing hydroxylamine used when the deposit DP is removed.

The invention made by the present inventors was specifically described according to the foregoing embodiments. Obviously, the present invention is not limited to the embodiments and can be changed in various ways without departing from the scope of the invention.

What is claimed is:

1. A semiconductor device comprising:
a wire layer including a first layer made of titanium, a second layer that is arranged over the first layer and is made of titanium nitride, a third layer that is arranged over the second layer and contains aluminum, and a fourth layer that is arranged over the third layer and is made of titanium nitride;
a side protective film that is arranged over a side of the wire layer and has chemical resistance to hydroxylamine and conductivity;
an interlayer insulating film that covers the wire layer and the side protective film and has via holes, and
via plugs that are arranged in the via holes and are electrically coupled to the wire layer.

2. The semiconductor device according to claim 1,
wherein the side protective film is made of a nitride of a material of the wire layer.

3. The semiconductor device according to claim 2,
wherein the fourth layer laterally protrudes from a side of the third layer arranged near the fourth layer.

4. The semiconductor device according to claim 3,
wherein a relationship of X>h×(tan θ2−tan θ1)/(tan θ1×tan θ2) is satisfied where h is a thickness of the third layer, X is a distance of lateral protrusion of the fourth layer from the side of the third layer arranged near the fourth layer, θ1 is an angle formed between the side of the third layer and the fourth layer, and θ2 is an angle formed between an inner wall surface of the via hole and a top surface of the interlayer insulating film.

5. The semiconductor device according to claim 3,
wherein a relationship of X>(A/2+Y−L/2)×(tan θ2−tan θ1)/2×tan θ1 where X is a distance of lateral protrusion of the fourth layer from the side of the third layer arranged near the fourth layer, θ1 is an angle formed between the side of the third layer and the fourth layer, θ2 is an angle formed between an inner wall surface of the via hole and a top surface of the interlayer insulating film, A is an opening width of the via hole at the same height as a top surface of the wire layer, and L is a width of the fourth layer.

6. The semiconductor device according to claim 1,
wherein the side protective film is a CVD film.

7. The semiconductor device according to claim 6,
wherein the side protective film is made of titanium nitride.

8. The semiconductor device according to claim 1, further comprising an antireflection film arranged over the fourth layer.

9. A method of manufacturing a semiconductor device, comprising the steps of:
forming a wire layer including a first layer made of titanium, a second layer that is arranged over the first layer and is made of titanium nitride, a third layer that is arranged over the second layer and contains aluminum, and a fourth layer that is arranged over the third layer and is made of titanium nitride;
forming a side protective film that is arranged over a side of the wire layer and has chemical resistance to hydroxylamine and conductivity;
forming an interlayer insulating film that covers the wire layer and the side protective film;
forming via holes in the interlayer insulating film by etching the interlayer insulating film;
cleaning surfaces of the via holes with a chemical solution containing hydroxylamine, and
forming via plugs arranged in the via holes so as to be electrically coupled to the wire layer.

10. The method of manufacturing a semiconductor device according to claim 9,
wherein the side protective film is formed by nitriding a side of the wire layer.

11. The method of manufacturing a semiconductor device according to claim 10,
wherein in the step of forming the wire layer, the fourth layer laterally protrudes from a side of the third layer arranged near the fourth layer.

12. The method of manufacturing a semiconductor device according to claim 11,
wherein a relationship of X>h×(tan θ2−tan θ1)/(tan θ1×tan θ2) is satisfied where h is a thickness of the third layer, X is a distance of lateral protrusion of the fourth layer from the side of the third layer arranged near the fourth layer, θ1 is an angle formed between the side of the third layer and the fourth layer, and θ2 is an angle formed between an inner wall surface of the via hole and a top surface of the interlayer insulating film.

13. The method of manufacturing a semiconductor device according to claim 11,
wherein a relationship of X>(A/2+Y−L/2)×(tan θ2−tan θ1)/2×tan θ1 where X is a distance of lateral protrusion of the fourth layer from the side of the third layer arranged near the fourth layer, θ1 is an angle formed between the side of the third layer and the fourth layer, θ2 is an angle formed between an inner wall surface of the via hole and a top surface of the interlayer insulating film, A is an opening width of the via hole at the same height as a top surface of the wire layer, and L is a width of the fourth layer.

14. The method of manufacturing a semiconductor device according to claim 9,
wherein the side protective film is formed by CVD over the side of the wire layer.

15. The method of manufacturing a semiconductor device according to claim 14,
wherein the side protective film is made of titanium nitride.
